(19) United States
(12) Patent Application Publication
(10) Pub. No.: US 2012/0222720 A1
(43) Pub. Date: Sep. 6, 2012

(54) SOLAR PANEL ASSEMBLIES INCLUDING PIVOTALLY MOUNTED SOLAR CELLS AND RELATED METHODS

(75) Inventors: Naga Chandrasekaran, Boise, ID (US); Gurtej S. Sandhu, Boise, ID (US)

(73) Assignee: MICRON TECHNOLOGY, INC., Boise, ID (US)

(21) Appl. No.: 13/038,139

(22) Filed: Mar. 1, 2011

(51) Int. Cl. H01L 31/052; B23P 11/00; H01L 31/18

(52) U.S. Cl. 136/246; 29/890.033; 29/428

(57) ABSTRACT

A solar panel assembly may comprise a support member, a plurality of elongate solar cells, at least one motive member, and at least one actuator. Each elongate solar cell of the plurality may be pivotally coupled to the support member at a first location on each elongate solar cell, and each motive member may be pivotally coupled to each elongate solar cell of the plurality of elongate solar cells at a second location on each elongate solar cell, the second location offset a distance from the first location. Additionally, each actuator may be operably coupled to the at least one motive member. A method of operating a solar panel assembly may comprise rotating each of a plurality of elongate solar cells within the solar panel assembly relative to each other of the plurality of elongate solar cells within the solar panel assembly.

### TECHNICAL FIELD

Embodiments of the present disclosure relate to elongate solar cells and assemblies thereof and, additionally, to methods of assembling elongate solar cells into assemblies and to apparatus useful in performing such methods. Specific embodiments relate to assemblies that include a mechanism for rotating pivotally mounted elongate solar cells within the assemblies, such as for tracking and maximizing receipt of solar radiation, and related methods.

### BACKGROUND

In order to increase the surface area of a bulk semiconductor substrate such as a semiconductor wafer that may for example be utilized for collecting solar energy, a wafer may be processed and cut through a thickness thereof into a large number of thin elongate solar cells, called “slivers.” The elongate solar cells, which have come to be known in the art as “slivers” are generally in a parallelepiped form with a relatively high aspect ratio of length to height and width, or thickness. The elongate solar cells that are cut from the wafer may then be arranged on a substrate with one or both major faces positioned to receive solar radiation, and conductively connected to form an array or sub-array for a solar collecting panel.

Such thin, elongate structures are also known by those of ordinary skill in the art as substrate slivers, elongate substrates, sliver substrates, substrate slivers, plank substrates, slivers, sliver structures, or merely slivers. Further, a thickness of an elongate solar cell is typically four to one hundred times smaller than a height thereof. The length and height of an elongate solar cell define the dimensions of opposing major faces of the structure. The thickness or width of an elongate solar cell is the distance between opposing major faces of the elongate solar cell. A representative elongate solar cell may be about 10 to about 120 mm long, about 0.5 to about 5 mm high, and about 15 to about 400 microns thick. Of course, these dimensions may vary depending on the intended application for the elongate solar cell and the type and dimensions of a bulk semiconductor substrate from which an elongate solar cell is severed.

As noted above, one conventional use for elongate solar cells is as photovoltaic devices or as solar cells assembled with a large number of other elongate solar cells to form a solar panel. Each elongate solar cell may be configured as a small solar cell also known as a sliver, solar sliver, solar sliver cell, or the like. Elongate solar cells can be produced by processes such as those described in “HighVo (High Voltage) Cell Concept” by S. Scheibenstock, S. Keller, P. Fath, G. Willeke and E. Bucher, Solar Energy Materials & Solar Cells Vol. 65 (2001), pages 179-184 (“Scheibenstock”), and in International Patent Application Publication No. WO 02/45143 (“the Sliver patent”). The latter document describes processes for producing a large number of thin (generally <150 μm) elongate silicon substrates from a single conventional silicon wafer, where the dimensions of the major faces of resulting thin elongate substrates are such that their total surface area is far greater than a major surface of the original silicon wafer. Such elongate substrates are referred to in the Sliver patent as “sliver substrates.” The Sliver patent also describes processes for forming solar cells on sliver substrates, referred to as “sliver solar cells.” The word “sliver” generally refers to a sliver substrate or sliver structure which may or may not incorporate one or more solar cells. The word “SLIVER” is a registered trade mark of Origin Energy Solar Pty Ltd, Australian Registration No. 933476.

In general, elongate solar cells can be single-crystal solar cells or multi-crystalline solar cells formed from elongate substrates. The elongate substrates are conventionally formed in a batch process by cutting a series of parallel elongate slots through a thickness of a silicon wafer to define a corresponding series of mutually parallel, thin elongate substrates separated from one another along their adjacent lengths and heights and joined together at their outer ends by the remaining portions of the wafer, referred to as the wafer frame. Solar cells can be formed from the elongate substrates while they remain in the wafer frame, and subsequently separated from each other and from the wafer frame to provide a set of individual elongate solar cells.

Solar panel assemblies including elongate solar cells have been utilized in ways similar to convention solar panel assemblies. A solar collecting surface of each of the elongate solar cells is positioned parallel to a solar collecting surface of each other elongate solar cell within the solar panel assembly and fixed to a common substrate. If the solar collecting surfaces of the solar panel assembly are to be moved, it requires the movement of the entire solar panel assembly. In order for the solar collecting surfaces to track the relative movement of the sun, the relatively bulky, heavy solar panel assembly must be mounted on a movable structure and relatively large motors and an associated drive train is required to move the entire solar panel assembly. Further, there must be sufficient space around any moveable solar panel assembly to accommodate the full range of motion of the solar panel assembly. Additionally, moveable solar panel assemblies must be positioned above supporting surfaces such as a roof or the ground, allowing clearance space for motion therebetween. This requirement may make the solar panel assembly unsightly and susceptible to significant wind loads, among other problems.

Even solar panel assemblies that are not configured to move to track the sun may have inherent problems at certain sites. If the solar collecting surface of the solar panel assembly is to be efficient, it must be oriented at a specific angle relative to the sun, which may require the solar panel assembly to be installed at an angle relative to the sun that is different than an angle of a mounting surface. In view of this, the solar panel assembly may have at least one end that is spaced up and away from a mounting surface, which may be unsightly and may make the solar panel assembly susceptible to significant wind loads as well as collection of leaves, snow and other debris thereunder, among other problems.

In view of the foregoing, improved assemblies including elongate solar cells and improved methods of manufacturing assemblies utilizing elongate solar cells and improved methods of operating solar panel assemblies would be desirable.

### BRIEF DESCRIPTION OF THE DRAWINGS

FIG. 1 shows a top view of a solar panel assembly according to an embodiment of the present invention.

FIG. 2 shows a partial cross-sectional view of the solar panel assembly of FIG. 1.

FIG. 3A shows a partial side view of a solar panel assembly having an elongate support member according to an embodiment of the present invention.

FIG. 3B shows a partial side view of the solar panel assembly of FIG. 3A having a plurality of elongate solar cells rotated to a second position.

FIG. 4A shows a perspective view of an elongate solar cell for a solar panel assembly such as shown in FIG. 1.

FIG. 4B shows a cross-sectional view of the elongate solar cell of FIG. 4A.

FIGS. 5 through 16 illustrate processes for manufacturing a solar panel assembly, such as shown in FIG. 1.

FIG. 5 shows an isometric view of a semiconductor wafer for utilization in making elongate solar cells.

FIG. 6 shows an isometric view of the semiconductor wafer of FIG. 5 including elongate solar cell precursor structures.

FIG. 7 shows an isometric view of a transfer structure attached to the elongate solar cell precursor structures of the semiconductor wafer of FIG. 6.

FIG. 8 shows an isometric view of the elongate solar cell precursor structures of FIG. 7 singulated from the wafer to form elongate solar cells attached to the transfer structure.

FIG. 9 shows a side view of the elongate solar cells attached to the transfer structure of FIG. 8, the elongate solar cells further attached to an expandable fixture.

FIG. 10 shows a side view of the elongate solar cells on the expandable fixture of FIG. 7, wherein the expandable fixture is in an expanded position and a substrate is positioned over and attached to the elongate solar cells.

FIG. 11 shows a side view of the elongate solar cells attached to the transfer structure of FIG. 8, the elongate solar cells further attached to a corrugated substrate of another expandable fixture.

FIG. 12 shows a side view of a substrate attached to the expandable fixture of FIG. 11 in an expanded position, prior to the substrate becoming corrugated.

FIG. 13 shows a side view of the substrate of FIGS. 11 and 12 in a flattened configuration having the elongate solar cells attached thereto and a substrate positioned over and attached to the elongate solar cell.

FIG. 14 shows a side view of the elongate solar cells attached to the transfer structure of FIG. 7, the elongate solar cells further attached to a deformable substrate of yet another expandable fixture.

FIG. 15 shows a side view of the deformable substrate of FIG. 14 in a stretched and plastically deformed state having the elongate solar cells attached thereto and a substrate positioned over and attached to the elongate solar cells.

FIG. 16 shows a side view of an assembly having a plurality of elongate solar cells positioned on a substrate and wired together.

FIG. 17 shows a top view of a solar panel assembly including a transparent sheet member according to an embodiment of the present invention.

FIG. 18A shows a partial cross-sectional view of a solar panel assembly having solar collecting surfaces positioned perpendicular to incident solar radiation according to an embodiment of the present invention.

FIG. 18B shows a partial cross-sectional view of a solar panel assembly having solar collecting surfaces positioned in another position and perpendicular to incident solar radiation according to an embodiment of the present invention.

FIG. 19 shows a cross-sectional view of a sensor

FIG. 20A shows a partial cross-sectional view of a solar panel assembly having solar collecting surfaces positioned to direct reflected solar radiation toward adjacent solar collecting surfaces according to an embodiment of the present invention.

FIG. 20B shows a partial cross-sectional view of a solar panel assembly having solar collecting surfaces positioned in another position to direct reflected solar radiation toward adjacent solar collecting surfaces according to an embodiment of the present invention.

FIG. 21 shows a partial cross-sectional view of a solar panel assembly mounted to a pivot according to an embodiment of the present invention.

### DETAILED DESCRIPTION

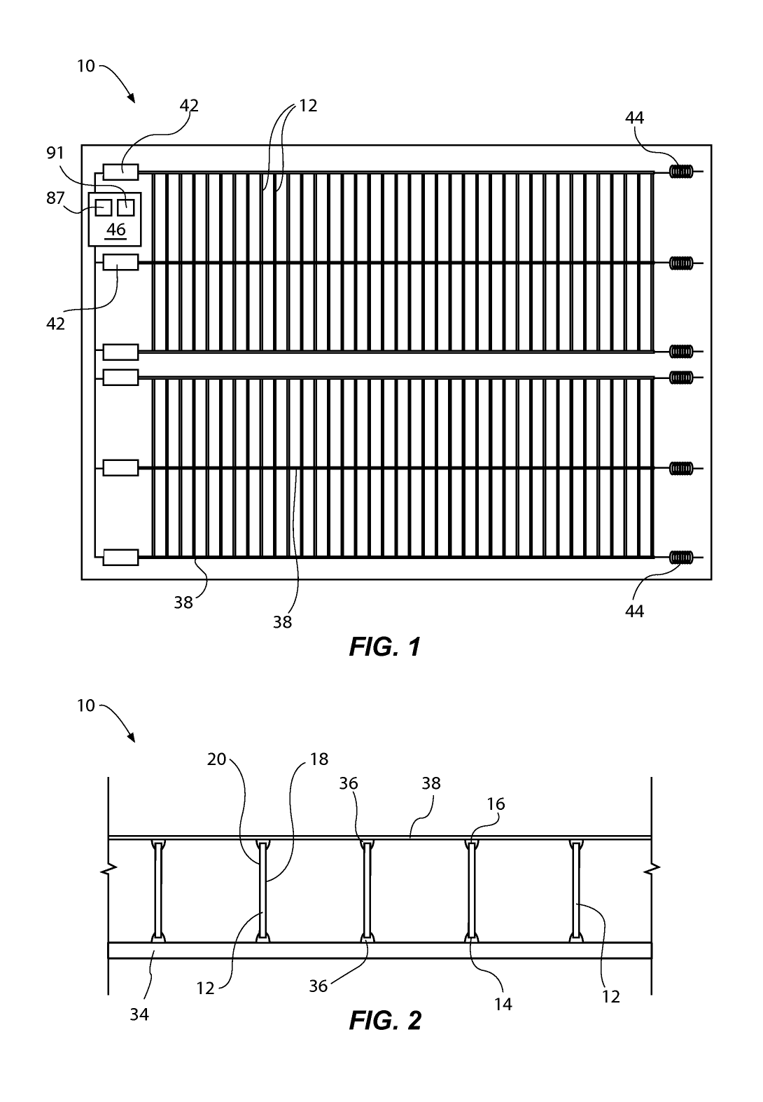

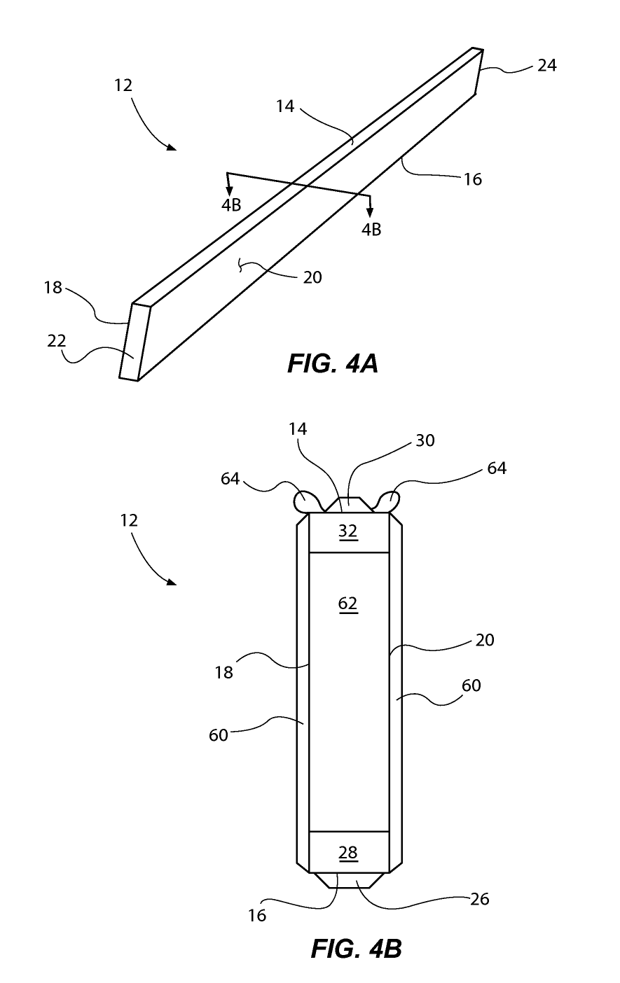

A solar panel assembly 10, such as is shown in FIGS. 1 and 2, may include a plurality of elongate solar cells 12. As shown in additional detail in FIGS. 4A and 4B, each elongate solar cell 12 of the plurality of elongate solar cells 12 may have a first edge 14 (e.g., a first elongate edge) and an opposing, second edge 16 (e.g., a second elongate edge). Each elongate solar cell 12 may also have a first major face 18 and an opposing second major face 20. Each of the first and second major faces 18 and 20 of the elongate solar cells 12 may be configured as solar collecting surfaces and each of the elongate solar cells 12 may, as desired, be configured as a bifacial solar cell. The elongate solar cells 12 may also have a first end 22 and an opposing second end 24 (shown in FIG. 4A). A length of the first and second ends 22 and 24 defines a height of each of the elongate solar cells 12 and corresponds to a distance between the first edge 14 and the second edge 16. However, other sizes and shapes of the elongate solar cell structure are contemplated herein.

Each elongate solar cell 12 may be a solid state device that converts the energy of sunlight or other light or radiant energy sources into electricity by the photovoltaic effect. A conductive material such as a metal 26 may be included along the second edge 16 to provide an electrical path to an n-doped material region 28 of the elongate solar cell 12. Similarly, a conductive material such as a metal 30 may be included along the first edge 14 to provide an electrical path to a p-type doped material region 32 of the elongate solar cell 12.

Referring again to FIGS. 1 and 2, the plurality of elongate solar cells 12 may be spaced apart from one another and each elongate solar cell 12 of the plurality of elongate solar cells 12 may be electrically coupled to another elongate solar cell 12 of the plurality of elongate solar cells 12, such as by one or more of wires (FIG. 16), electrical traces and other electrically conductive structures. For example, the metal 26 of an elongate solar cell 12 may be electrically coupled to the metal 30 of an adjacent elongate solar cell 12, and so on.

Each elongate solar cell 12 of the plurality of elongate solar cells 12 may be positioned in an array, substantially parallel to each other elongate solar cell 12 of the plurality of elongate solar cells 12. In some embodiments, such as shown in FIGS. 1 and 2, the first edges 14 of each elongate solar cell 12 may be coupled to a support member, such as a substrate 34, which may space each of the first edges 14 of the plurality of elongate solar cells 12 relative to the first edges 14 of adjacent elongate solar cells 12 of the plurality and maintain the relative position of the first edges 14 of the plurality of elongate solar cells 12.

In some embodiments, the first edges 14 of the plurality of elongate solar cells 12 may be coupled to the substrate 34 by a pivotal connection 36, which may allow rotation of each of the elongate solar cells 12 of the array through an arc about the pivotal connection 36. For example, each pivotal connection 36 may comprise a relatively flexible material, such as a flexible adhesive material, a film or fabric carrying an adhesive bonded to a first edge 14 and the substrate 34, or a preformed element having a flat base with an adhesive on the underside bonded to the substrate 34, and an upwardly-protruding flexible segment having a channel formed therein receiving a first edge 14 of an elongate solar cell 12.

As further shown in FIGS. 1 and 2, each of the elongate solar cells 12 may be positioned with their major faces 18 and 20 positioned at a non-parallel angle with respect to the substrate 34, the second edges 16 of the plurality of elongate solar cells 12 away from and out of contact with the substrate 34. Additionally, the second edges 16 of the plurality of elongate solar cells 12 are movable relative to the substrate 34, due to the presence of the pivotal connections between the substrate 34 and first edges 14.

The second edges 16 of the plurality of elongate solar cells 12 of the array are, also, each coupled by a pivotal connection 36 to at least one motive member (identified by reference numeral 38 in FIGS. 1 and 2, which may extend over the second edges 16 of the plurality of elongate solar cells 12. For example, each pivotal connection 36 may comprise a relatively flexible material, such as a flexible adhesive material, a film or fabric carrying an adhesive bonded to a second edge 16 and the at least one motive member, or a preformed element having a flat base with an adhesive on the underside bonded to the at least one motive member, and an upwardly-protruding flexible segment having a channel formed therein receiving a second edge 16 of an elongate solar cell 12.

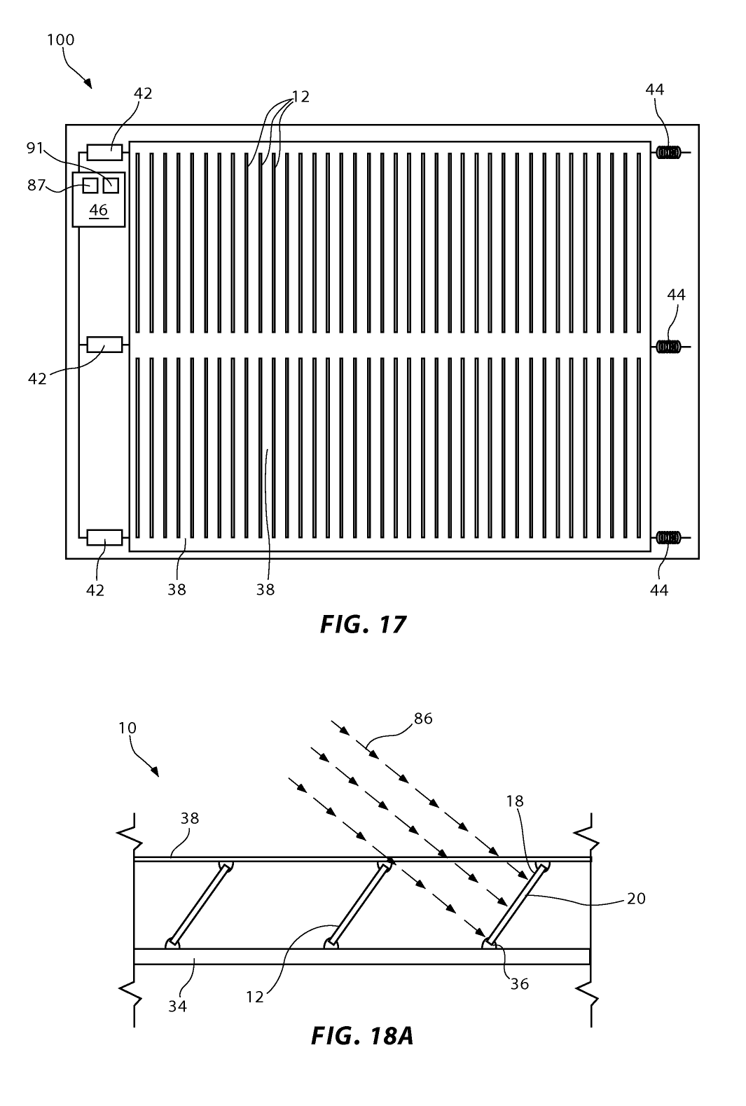

In some embodiments, each motive member may be configured as an elongate member 38 (FIGS. 1 and 2), such as a beam, or as a sheet member 40 (FIG. 17), which may be substantially transparent, allowing passage of solar radiation therethrough. For example, the motive member may be a transparent sheet member 40 (FIG. 17), such as a glass or polycarbonate sheet, which may cover the entirety of each of the plurality of elongate solar cells 12 of one or more arrays. In additional embodiments, each motive member may be configured as a relatively thin elongate member 38 (FIGS. 1 and 2), such as a wire or a cable.

The second edges 16 of the plurality of elongate solar cells 12 of one or more arrays may be coupled together and coupled to at least one actuator 42 and at least one biasing structure 44 by each motive member 38, 40 that extends thereover or at an edge thereof. Each motive member 38, 40 may be operably coupled to an actuator 42, such as by having a first end coupled to an actuator 42 and may optionally be operably coupled to a biasing member structure 44, such as by having a second end coupled to a biasing structure 44. For example, each actuator 42 may comprise at least one of an electro-mechanical actuator, a transducer, a piezoelectric actuator, a motor, a stepper motor, a screw jack, a ball screw, a roller screw, a rack and pinion, a winch, a comb drive, a thermal bimorph, and an electroactive polymer. An actuator 42 may be operably coupled to elongate solar cells 12 to receive electrical power therefrom for operation. Each biasing structure 44 may comprise at least one of a coil spring, a torsion spring, a leaf spring, an elastic material, and a weighted device. In view of this, forces may be applied to each motive member 38, 40 by each respective actuator 42 and biasing structure 44 to facilitate the simultaneous movement of each second edge 16 of the plurality of elongate solar cells 12 of one or more arrays, which may cause the rotation of each elongate solar cell 12 relative to one another and in an arc relative to the substrate 34 responsive to linear motion of a motive member 38,40 which is converted in part to rotational movement by pivotal connections 36. The solar panel assembly 10 may further include a controller 46 in electrical communication with each actuator 42 and programmed to control operation thereof.

In addition to each of the plurality of elongate solar cells 12 being electrically coupled together, such as by wiring 84 (FIG. 16) and/or electrical traces (i.e., electrical traces formed on the substrate 34 and/or a member 38, 40), the plurality of elongate solar cells 12 may be electrically coupled to the controller 46 to provide power thereto. Additionally, although the elongate solar cells 12 may be bifacial; having solar collecting surfaces on both of their opposing major faces 18 and 20, and may be visually symmetrical, the elongate solar cells 12 are not electrically symmetrical (i.e., each elongate solar cell 12 has a polarity). In view of this, the orientation and polarity of each elongate solar cell 12 affects the electrical connection of each elongate solar cell 12 to other elongate solar cells 12 of the solar panel assembly 10. Additionally, both series and parallel connection schemes for a plurality of elongate solar cells 12 are contemplated as within the scope of the disclosure, such schemes being known to, and within the ability of, those of ordinary skill in the art.

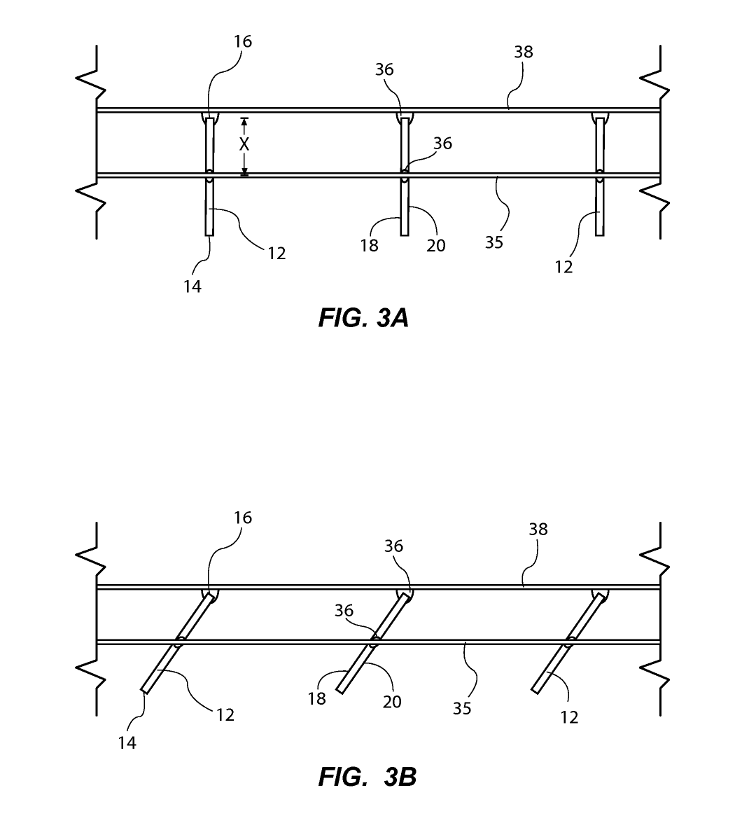

In some embodiments, such as shown in FIG. 3A, a support member, such as an elongate support structure 35, may be pivotally coupled to the ends 22, 24 of each elongate solar cell 12 of a plurality of elongate solar cells 12 at a first location on each elongate solar cell 12. At least one motive member 38 may be pivotally coupled to each elongate solar cell 12 at a second location on each elongate solar cell 12; the second location offset a distance X from the first location, where the elongate support structure 35 is attached. In view of this, when the motive member 28 is moved relative to the support structure 35 (or vice versa), each elongate solar cell 12 may rotate relative to each other elongate solar cell 12 of the plurality of elongate solar cells 12, such as shown in FIG. 3B. For example, each elongate solar cell 12 may rotate about the first location, where the support member may be attached. In some embodiments, the first location may be at about a center of each end 22, 24 of each elongate solar cell 12 and the second location may be at about an edge 16 of each elongate solar cell 12, such as shown in FIG. 3A. In additional embodiments, the first location may be at a first edge 14 of each elongate solar cell 12 and the second location may be at a second edge 16 of each elongate solar cell, such as shown in FIG. 2. However, as will be understood by a person of ordinary skill in the art, locations other than shown in FIGS. 2 and 3A would be satisfactory first and second locations for pivotally attaching a support member and a motive member 38 to each elongate solar cell 12 of a plurality of solar cells 12.

While embodiments of solar panel assemblies 10 are described as having elongate solar cells 12 with certain polarities relative to the solar panel assembly 10 and other components, such as the substrate 34, these polarities are provided as non-limiting examples. Additional embodiments may include elongate solar cells 12 having different polarities than those described with reference to the example embodiments and may include electrical connections that are appropriate for the particular orientation of the elongate solar cells 12 of the particular solar panel assembly 10. In some embodiments, each elongate solar cell 12 of the plurality of elongate solar cells 12 may have the same polarity as each other elongate solar cell 12 of the plurality of elongate solar cells 12. In additional embodiments, each elongate solar cell 12 of the plurality of elongate solar cells 12 may have the opposite polarity of each adjacent elongate solar cell 12 of the plurality of elongate solar cells 12.

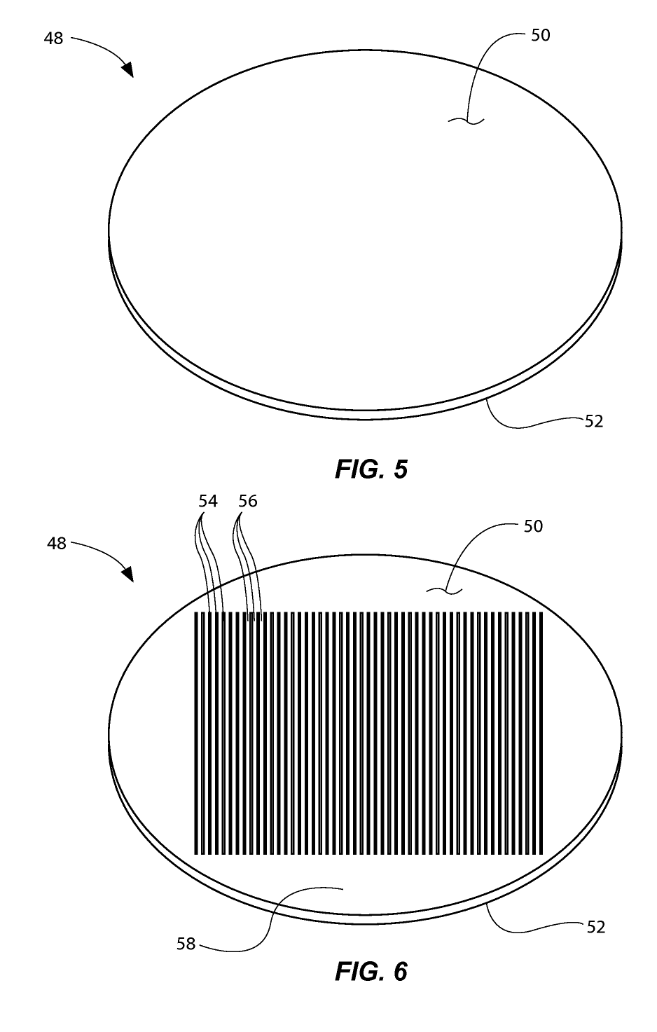

A process to manufacture solar panel assemblies 10 may first include manufacturing of the plurality of elongate solar cells 12 from a semiconductor wafer 48 such as a silicon wafer as shown in FIG. 5. The semiconductor wafer 48 may include a first major surface 50 and an opposing second major surface 52. The semiconductor wafer 48 may be a p-type semiconductor wafer such that at least a central region of the semiconductor wafer 48, between the first major surface 50 and the second major surface 52, may be doped with a p-type dopant. The semiconductor material near the first major surface 50 of the semiconductor wafer 48 may be relatively heavily doped with a p-type dopant, such as by a surface diffusion of one or more p-type dopants at the first major surface 50 of the semiconductor wafer 48. Additionally, the semiconductor material near the second major surface 52 of the semiconductor wafer 48 may be relatively heavily doped with an n-type dopant, such as by a surface diffusion of one or more n-type dopants at the second major surface 14 of the semiconductor wafer 48. While the present disclosure describes embodiments utilizing conventional, substantially circular, semiconductor wafers, the invention is not so limited and other bulk semiconductor substrates from which slivers comprising elongate solar cells may be severed may also be employed. Therefore, the term “wafer” as employed herein means and includes bulk semiconductor substrates in general.

As shown in FIG. 6, a plurality of elongated slots 54 may be formed in the semiconductor wafer 48, to define therebetween a plurality of elongate solar cell precursor structures 56 therebetween. For example, the slots 54 may be formed by one or more of sawing, such as by a diamond-edged dicing saw having a narrow blade, laser ablation, water-jet cutting, etching, such as by a wet anisotropic etch using potassium hydroxide solution (KOH), and other techniques recognized by one of ordinary skill in the art. Optionally, elongated slots 54 may be cut in various regions of the wafer 48 and in different directions to maximize usage of the semiconductor material of the wafer 48, and the wafer 48 may be further cut to form a plurality of wafer frames (not shown) from uncut portions of the wafer 48 surrounding each group of elongate solar cell precursor structures 56. After the slots 54 have been formed, the ends of each of the elongate solar cell precursor structures 56 may remain attached to a wafer frame 58. Optionally, after the slots 54 have been formed, a surface treatment may be applied to the major surfaces of the elongate solar cell precursor structures 56. For example, a roughening treatment may be applied to the major surfaces of the elongate solar cell precursor structures 56. Additionally, a conductive material layer, such as a conductive metal layer, may be provided on the upper and lower edges of each of the elongate solar cell precursor structures 56.

The elongate solar cell precursor structures 56 are elongated structures with a length that is typically much greater than its height and width and having ends attached to the wafer frame 58, each of the elongate solar cell precursor structures 56 and the wafer frame 58 being a unitary structure. Once the ends of an elongate solar cell precursor structure 56 have been singulated from the wafer frame 58 an elongate solar cell is formed.

As shown in FIGS. 4A and 4B, the first edge 14 may be formed from the first major surface 50 of the semiconductor wafer 48 as a result of forming the slots 54 into the semiconductor wafer 48. Similarly, the second edge 14 may be formed from the opposing second major surface 52 of the semiconductor wafer 48 by formation of slots 54. The first major face 18 and the opposing second major face 20 may be formed from the interior material of the semiconductor wafer 48 after the slots 54 are formed into the semiconductor wafer 48. Optionally, as shown in FIG. 4B, a material, such as an oxide 60, may coat the first and second major surfaces.

As seen in FIG. 4B, each elongate solar cell 12 has an interior body 62 formed of the semiconductor material of the semiconductor wafer that is made of a lightly p-type doped material. Each elongate solar cell 12 further includes a relatively heavily p-type doped material region 32 near the first edge 14 and a relatively heavily n-type doped material region 28 near the second edge 16. Optionally, each elongate solar cell 12 may include a thin oxide 60 on one or both of the first and second primary surfaces 18 and 20. As previously described, a conductive material such as a metal 26 may be included along the first edge 16 to provide an electrical path to the n-doped material region 28 to the elongate solar cell 12. Similarly, a conductive material such as a metal 30 may be included along the first edge 14 to provide an electrical path to the p-type doped material region 32 of the elongate solar cell 12. In one embodiment, a dielectric material 64 may additionally be applied along one or more edges of the elongate solar cell 12. The dielectric material 64 may be configured to increase the efficiency of the elongate solar cell 12.

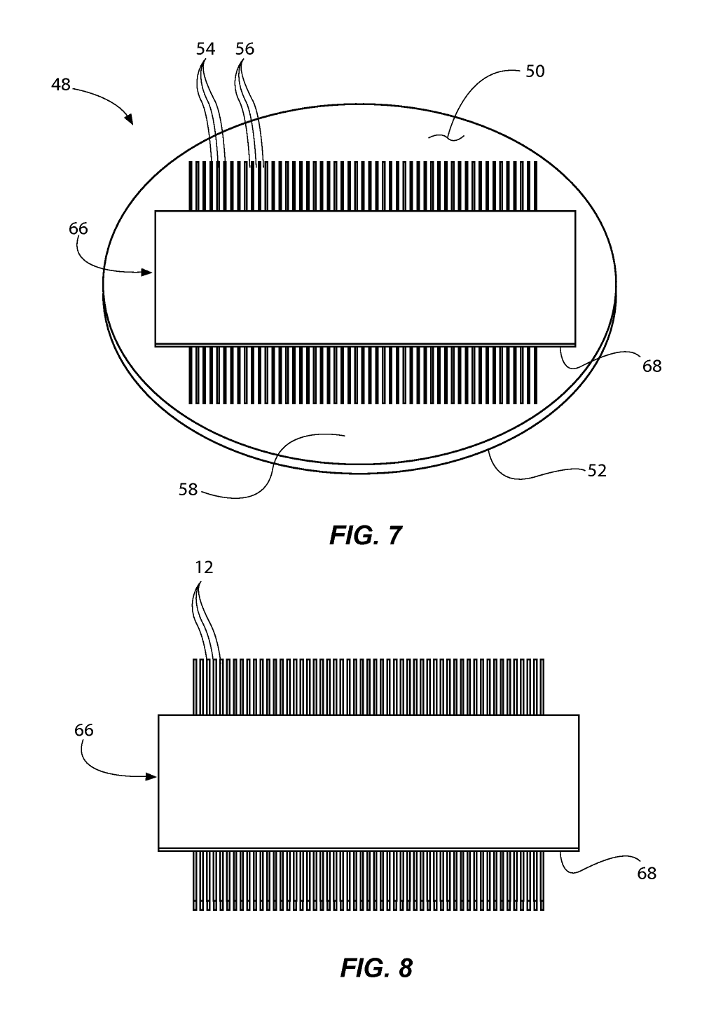

As shown in FIG. 7, after the elongate solar cell precursor structures 56 have been defined (as shown in FIG. 6), a transfer structure 66 having an adhesive surface 68 may be positioned over and adhered to one of the first edge 14 and the second edge 16 of each of the plurality of elongate solar cell precursor structures 56, or at least a group of elongate solar cell precursor structures 56 of the plurality of elongate solar cell precursor structures 56. For example, the adhesive surface 68 may be adhered to the second edge 16 of each of the plurality of elongate solar cell precursor structures 56. In some embodiments, the adhesive surface 68 may comprise a wax plate (free-standing or supported by a substrate for enhanced mechanical strength during handling) that may be relatively soft at the temperature at which it is applied to the second edges 16 of the elongate solar cell precursor structures 56, surrounding a portion of the second edge 16 of each elongate solar cell precursor structure 56 and adhering thereto. Optionally, the wax plate may be heated or otherwise softened prior to contacting and adhering to the elongate solar cell precursor structures 56. In additional embodiments, an adhesive layer 68 that is softenable by heat, light, or another energy source may be utilized, and softened prior to contact with and adhesion to the elongate solar cell precursor structures 56. If the adhesive layer 68 is heated, it may be heated to a temperature below about 400° C. to prevent thermal damage to the elongate solar cell precursor structures 56. Utilizing an adhesive layer 68 that is relatively soft and pliable during attachment allows the adhesive layer 68 to conform to and extend around a portion of the edge 14, 16 of the elongate solar cell precursor structures 56, which may provide excellent support and adhesion to the elongate solar cell precursor structures 56, and may prevent rotational, angular displacement of the elongate solar cells 12 relative to one another and mutual contact of the elongate solar cells 12 after they have been singulated from the wafer frame 58. In some embodiments, after the adhesive layer 68 has been positioned on the second edges 16 of the elongate solar cell precursor structures 56, the adhesive layer 68 may be treated so as to become stiffer; for example a wax plate may be cooled, prior to singulation of the elongate solar cells 12. In further embodiments, the adhesive layer 68 may remain relatively soft and pliable. As used herein, the terms “adhesive,” “adhering,” “adhere” and the like are to be interpreted in a broad and non-limiting sense, indicating only that a structure provides a bonding or other attachment function by which an elongate solar cell precursor structure or elongate solar cell may be held temporarily or permanently in a desired position. Similarly, any reference to attaching one structure to another herein is to be interpreted in a broad and non-limiting sense and encompasses a wide variety of attachment compositions, structures and mechanisms.

After the adhesive surface 68 of the transfer structure 66 has been attached to the elongate solar cell precursor structures 56, the elongate solar cell precursor structures 56 may be cut or otherwise singulated from the wafer frame 58 to provide a plurality of individual elongate solar cells 12 attached to the transfer structure 66, as shown in FIG. 8. In some embodiments, the transfer structure 66 may be attached to a central region of the elongate solar cell precursor structures 56 and the ends of the elongate solar cell precursor structures 56, where each elongate solar cell structure 56 attaches to the wafer frame 58, may be left open and accessible. The ends of the elongate solar cell precursor structures 56 may then be severed from the wafer frame 58, such as by one or more of sawing, such as by a dicing saw, laser ablation, water-jet cutting, and other techniques known to one of ordinary skill in the art. After the elongate solar cell precursor structures 56 have been cut to form a plurality of individual elongate solar cells 12, the plurality of individual elongate solar cells 12 may be simultaneously moved together as a unit by the transfer structure 66 for further processing, and the elongate solar cells 12 positions relative to one another may be maintained by the transfer structure 66.

The transfer structure 66 may then be manipulated to simultaneously move and position the individual elongate solar cells 12 onto an expandable fixture for individual positioning of the elongate solar cells 12 for installation into a solar panel assembly 10. In one embodiment, such as shown in FIG. 9, the expandable fixture 70 may include a plurality of fingers 72, each finger 72 corresponding and positioned with respect to an elongate solar cell 12 attached to the transfer structure 66. Each finger 72 may include a feature for the attachment of an elongate solar cell 12. For example, each finger 72 may have a geometric feature, such as a pocket, for receiving an edge 14, 16 of an elongate solar cell 12. In an additional example, each finger 72 may include an adhesive for bonding to an edge 14, 16 of an elongate solar cell 12. In a further example, each finger 72 may include one or more apertures in a face thereof in fluid communication with a vacuum source for forming a vacuum between each finger 72 and edge 14, 16 of an elongate solar cell 12.

Upon attaching the elongate solar cells 12 to the fingers 72 of the expandable fixture 70, the transfer structure 66 may be removed. To facilitate removal of the transfer structure 66, a treatment may be applied to the adhesive surface 68. For example, the adhesive surface 68 may be softened, melted, or otherwise weakened, such as by the application of heat, light, and/or chemicals. In some embodiments, the adhesive surface 68 (e.g., wax plate) may be broken down, such as by the application of heat and/or chemicals. For example, the adhesive surface 68 may be broken down by one or more of vaporization, liquefaction, volatilization, and dissolution.

After the transfer structure 66 has been removed, the expandable fixture 70 may be expanded by lateral movement of the fingers 72 away from one another in a direction transverse to the longitudinal axes of the fingers 72. During expansion of the expandable fixture 70, the plurality of fingers 72 of the expandable fixture 54 may become spaced apart and consequently orient the elongate solar cells 12 to a desired configuration.

Upon expansion of the expandable fixture 70, such as shown in FIG. 10, each of the elongate solar cells 12 secured thereto may be moved and spaced relative to adjacent elongate solar cells 12 on the expandable fixture 70 and each of the elongate solar cells 12 may be positioned in a desired orientation and the first edges 14 of the plurality of elongate solar cells 12 may be pivotally coupled to a support structure, such as a substrate 34. For example, an adhesive may be applied to the substrate 34, the first edges 14 of the plurality of elongate solar cells 12, or both, and then the first edges 14 of the plurality of elongate solar cells 12 may be positioned on the substrate 34. After the plurality of elongate solar cells 12 have been positioned on the substrate 34, the adhesive may be cured to a flexible structure to form the pivotal connection 36 between the plurality of elongate solar cells 12 and the substrate 34. In further embodiments, the ends 22, 24 of each of the elongate solar cells 12 may be coupled to an elongate support structure 35, such as shown in FIGS. 3A and 3B.

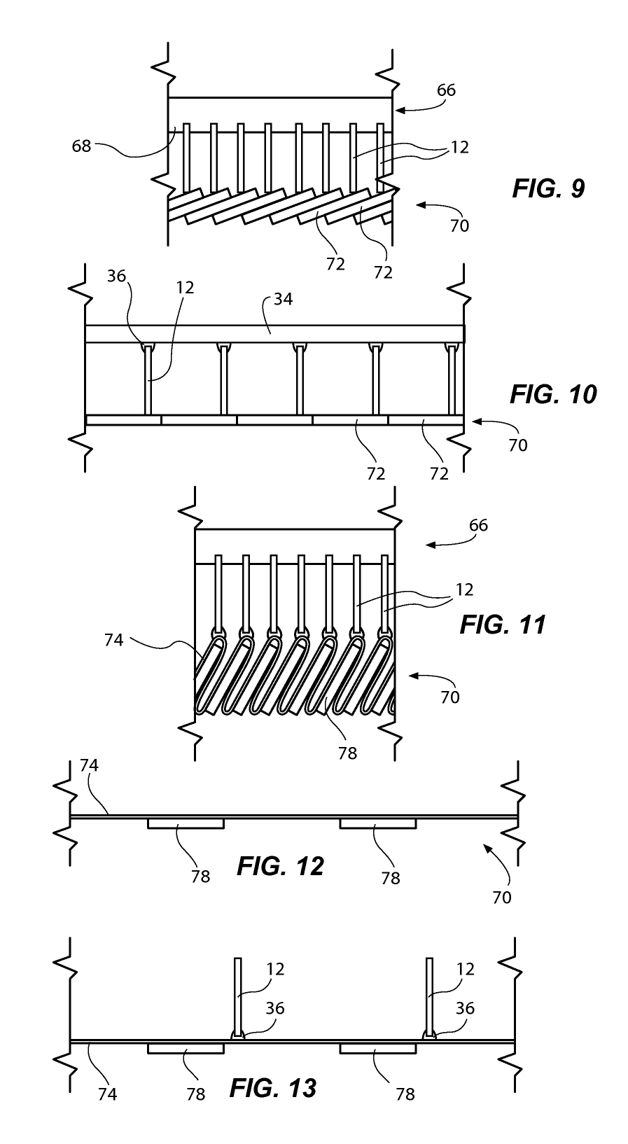

In additional embodiments, such as shown in FIG. 11, the expandable fixture 70 may include a corrugated substrate 74 having regions positioned for receiving the elongate solar cells 12. Each of the elongate solar cells 12 may be positioned respectively onto corresponding regions of the corrugated substrate 74 and may be attached to thereto, such as by an adhesive. In some embodiments, the corrugated substrate 74 may be permanently attached to fingers 78 of the expandable fixture 70 and may be reusable. In additional embodiments, the corrugated substrate 74 may be temporarily attached to the fingers 78 of the expandable fixture 70. For example, the corrugated substrate 74 may be freed from fingers 78 and utilized as the substrate 34 that is incorporated into the solar panel assembly 10 and the elongate solar cells 12 may be permanently attached to the corrugated substrate 74 by pivotal connections 36.

In one embodiment, as shown in FIGS. 11-13, a relatively flexible and substantially flat substrate 74 may be adhered to the fingers 78 when the expandable fixture 70 is in an expanded position, such as shown in FIG. 12. The expandable fixture 70 may then be contracted and the fingers 78 may cause the previously flat substrate 74 to form a corrugated substrate 74, as shown in FIG. 11.

Upon attaching the elongate solar cells 12 onto the corrugated substrate 74 of the expandable fixture 70, as shown in FIG. 11, the transfer structure 66 may be removed. To facilitate removal of the transfer structure 66, a treatment may be applied to the adhesive surface 68. For example, the adhesive surface 68 may be softened, melted, or otherwise weakened, such as by the application of heat, light, and/or chemicals. In some embodiments, the adhesive surface 68 (e.g., wax plate) may be broken down, such as by the application of heat and/or chemicals. For example, the adhesive surface 68 may be broken down by one or more of vaporization, liquefaction, volatilization, and dissolution.

After the transfer structure 66 has been removed, the expandable fixture 70 may be expanded. During expansion of the expandable fixture 70, the corrugated substrate 74 (FIG. 11) may be expanded transverse to the direction of fingers 78 and the corrugations may be flattened (FIG. 13) to provide the desired orientation of the elongate solar cells 12. Upon expanding of the expandable fixture 70 and flattening of the substrate 74, as shown in FIG. 13, each of the elongate solar cells 12 may, as a result, be moved and spaced relative to adjacent elongate solar cells 12 on the expandable fixture 70 and each of the elongate solar cells 12 may be positioned in a desired orientation for assembling into an assembly. Substrate 74 may be formed of an elastically or plastically deformable material, to provide a capability for spacing elongate solar cells laterally apart by an adjustable distance.

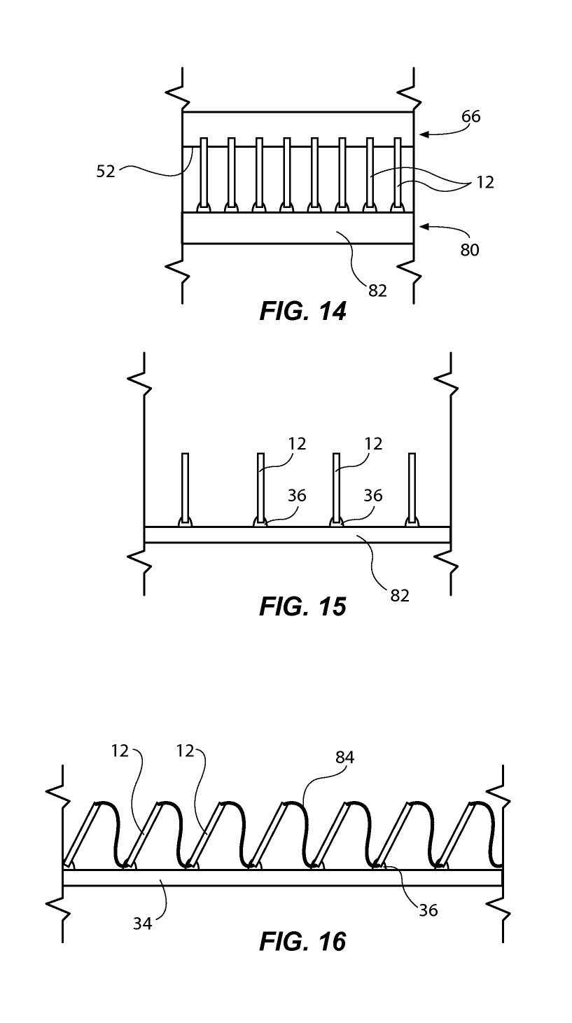

In further embodiments, such as shown in FIG. 14, an expandable fixture 80 may include a deformable substrate 82 that is capable of substantial stretching without rupturing.

Upon attaching the elongate solar cells 12 onto the deformable substrate 82 of the expandable fixture 80, the transfer structure 66 may be removed. To facilitate removal of the transfer structure 66 the adhesive surface 52 (e.g., wax plate) may be broken down, such as by the application of heat and/or chemicals. For example, the adhesive surface 68 may be broken down by one or more of vaporization, liquefaction, volatilization, and dissolution.

After the transfer structure 66 has been removed, the expandable fixture 80 may be expanded. During the expansion of the expandable fixture 80, the deformable substrate 82 may be deformed, such as by stretching, to provide the desired orientation and spacing of the elongate solar cells 12 positioned thereon, and secured at its edges to a frame to maintain shape. After the deformable substrate 82 has been deformed, and optionally during deformation, a treatment may be applied to relieve any elastic deformation of the deformable substrate 82, such that the deformable substrate 82 may be plastically deformed (i.e., permanently deformed) to provide a permanent, desired spacing for elongate solar cells 12. For example, a deformable substrate 82 may comprise a thermoplastic polymer material and may be exposed to a heat treatment to facilitate plastic deformation of the deformable substrate 82.

Upon expansion of the expandable fixture 80 and the plastic deformation of the deformable substrate 82, such as shown in FIG. 15, each of the elongate solar cells 12 may be moved and spaced relative to adjacent elongate solar cells 12 on the expandable fixture 80 and each of the elongate solar cells 12 may be positioned in a desired orientation and spacing for assembling into an assembly. For example, the deformable substrate 82 may be utilized as the substrate 34 in a solar panel assembly, and each of the plurality of elongate solar cells 12 may be coupled to the deformable substrate 82 by a hinged connection 36. In additional embodiments, the plurality of elongate solar cells 12 may be coupled to another substrate 34 and the plurality of elongate solar cells 12 may be separated from the deformable substrate 82.

As the plurality of elongate solar cells 12 is positioned at an angle relative to the substrate 34, the final spacing between each elongate solar cell 12 and an adjacent elongate solar cell 12 of the plurality of elongate solar cells 12 (i.e., the final spacing between the first edges 14 of the respective elongate solar cells 12 of the plurality) may be less than the height of each elongate solar cell 12. For a non limiting example, the final spacing between each elongate solar cell 12 and an adjacent elongate solar cell 12 of the plurality of elongate solar cells 12 may be about the height of the elongate solar cells divided by the square root of two (i.e., the closest spacing that may allow the elongate solar cells 12 to be positioned at a 45 degree angle relative to the substrate 34 without overlapping). In additional embodiments, the final spacing between each elongate solar cell 12 and an adjacent elongate solar cell 12 of the plurality of elongate solar cells 12 (i.e., the final spacing between the first edges 14 of the respective elongate solar cells 12 of the plurality) may be greater than or equal to the height of each elongate solar cell 12.

In some embodiments, such as shown in FIG. 16, conductors in the form of wiring 84 may be provided as a wire mesh extending along the ends 22, 24 of the elongate solar cells 12, coupling the elongate solar cells 12 in series, a first edge 14 of an elongate solar cell 12 coupled to a second edge 16 of an adjacent elongate solar cell 12, and so on. By locating the wiring 84 at the ends 22, 24 of the elongate solar cells 12, the wiring 84 may not cast any significant shadows on the primary surfaces 18, 20 (i.e., the solar collecting surfaces) of the elongate solar cells 12.

In some embodiments, the substrate 34 may include electrically conductive traces formed thereon or applied thereto (i.e., the substrate 34 may be pre-wired). The electrically conductive traces may be aligned with the elongate solar cells 12 and electrically coupled to the conductive material 26, 30 on the first and first edges 14 and 16 of each of the elongate solar cells 12. In additional embodiments, electrically conductive traces may be provided on the substrate 34 and coupled to the elongate solar cells 12 after the elongate solar cells 12 have been adhered to the substrate 34.

After the plurality of elongate solar cells 12 have been pivotally coupled to the substrate, and optionally, after the plurality of elongate solar cells 12 have been electrically coupled together, one or more motive members 38, 40 may be positioned over the second edges 16 of the plurality of elongate solar cells 12 and pivotally coupled thereto by pivotal connections 36. In some embodiments, at least one elongate motive member 38 may be coupled to the second edges 16 of the plurality of elongate solar cells 12. For example, a plurality of elongate motive members 38 (i.e., beams, wires, cables or other elongate structures) may be coupled to the second edges 16 of the plurality of elongate solar cells 12, such as shown in FIG. 1. An adhesive may be applied to the second edges 16 of the plurality of elongate solar cells 12, to the plurality of elongate motive members 38, or to both. The elongate motive members 38 may then be positioned over and on the second edges 16 of the plurality of elongate solar cells 12, the elongate motive members 38 extending in a direction generally perpendicular to the orientation of the length of the plurality of elongate solar cells 12. After the elongate motive members 38 have been positioned on the second edges 16 of the plurality of elongate solar cells 12, the adhesive may be cured to a flexible structure to form the pivotal connections 36 between the plurality of elongate solar cells 12 and the elongate motive members 38. In additional embodiments, a solar panel assembly 100 may include a transparent sheet motive member 40 (i.e., a glass sheet, a polymer sheet, or another substantially rigid transparent sheet material) coupled to the second edges 16 of the plurality of elongate solar cells 12, such as shown in FIG. 17. In such embodiments, an adhesive may be applied to the second edges 16 of the plurality of elongate solar cells 12, to the transparent sheet motive member 40, or to both. The transparent sheet member 40 may then be positioned over and on the second edges 16 of the plurality of elongate solar cells 12. In some embodiments, as shown in FIG. 16, the transparent sheet motive member 40 may extend over and completely cover the plurality of elongate solar cells 12. After the transparent sheet member 40 has been positioned on the second edges 16 of the plurality of elongate solar cells 12, the adhesive may be cured to provide flexible structures to form the hinged connections 36 between the plurality of elongate solar cells 12 and the transparent sheet motive member 40.

Next, the one or more motive members 38, 40 (i.e., the elongate members 38 or the transparent sheet member 40) may be coupled to one or more actuators 42 and biasing structures 44. A first end of each motive member 38, 40 may be mechanically coupled to an actuator 42, such as by a cable. A second end of each motive member 38, 40 may be mechanically coupled to biasing member 44, such as by a cable. Additionally, each actuator 42 and biasing structure 44 may be coupled to a fixed structure of the solar panel assembly 10, such as the substrate 34 or a frame (not shown).

In further embodiments, a simple mechanical fixture similar to that used for venetian blinds may be coupled to an actuator 42 and may be utilized to rotate each of the plurality of elongate solar cells 12.

After each actuator 42 is coupled to a fixed structure of the solar panel assembly 10, each actuator 42 may be electrically coupled to the controller 46. Additionally, the controller 46, and each actuator 42 coupled thereto, may be electrically coupled to the plurality of elongate solar cells 12, which may be used to provide electrical power to the controller 46 and each actuator 42.

In operation, a solar panel assembly 10 may be positioned in a location that is regularly exposed to solar radiation, such as the roof of a building or another outdoor area with relatively unobstructed exposure to the sun. As the angle of incident solar radiation from the sun changes relative to the solar panel assembly 10 throughout the day, each motive member 38, 40 may be moved by each respective actuator 42 and biasing member 44 to cause each elongate solar cell 12 of the plurality of elongate solar cells 12 to rotate relative to one another and relative to the primary direction of incident solar radiation. The rotation of each of the plurality of solar cells 12 throughout the day may be used to position the solar collecting surfaces (i.e., major faces 18 and 20) of each of the plurality of elongate solar cells 12 relative to the incident solar radiation to facilitate an optimized collection of solar radiation by the solar panel assembly 10 throughout the day.

In some embodiments, the controller 46 may be programmed to communicate with the actuators 42 and orient a solar collecting surface (i.e., major faces 18 and 20) of each of the plurality of elongate solar cells 12 to a position that facilitates near-maximum absorption of solar radiation by that solar collecting surface. For example, as shown in FIGS. 17A-17B, a solar collecting surface, such as a major face 18, 20, of each of the plurality of elongate solar cells 12 may be oriented throughout the day to be relatively perpendicular to the primary direction of incident solar radiation 86 (i.e., a solar collecting surface of each of the plurality of elongate solar cells 12 may be positioned to track the position of the sun throughout the day). By way of elaboration, data associated with sun angle for every day and time of day specific to a particular latitude may be loaded into memory 85 associated with the controller 46, and used by a processor 87 of the controller 46 (FIGS. 1 and 16) to cause actuators 42 to rotate the plurality of elongate solar cells 12 of the array to an optimum angle for receipt of solar radiation.

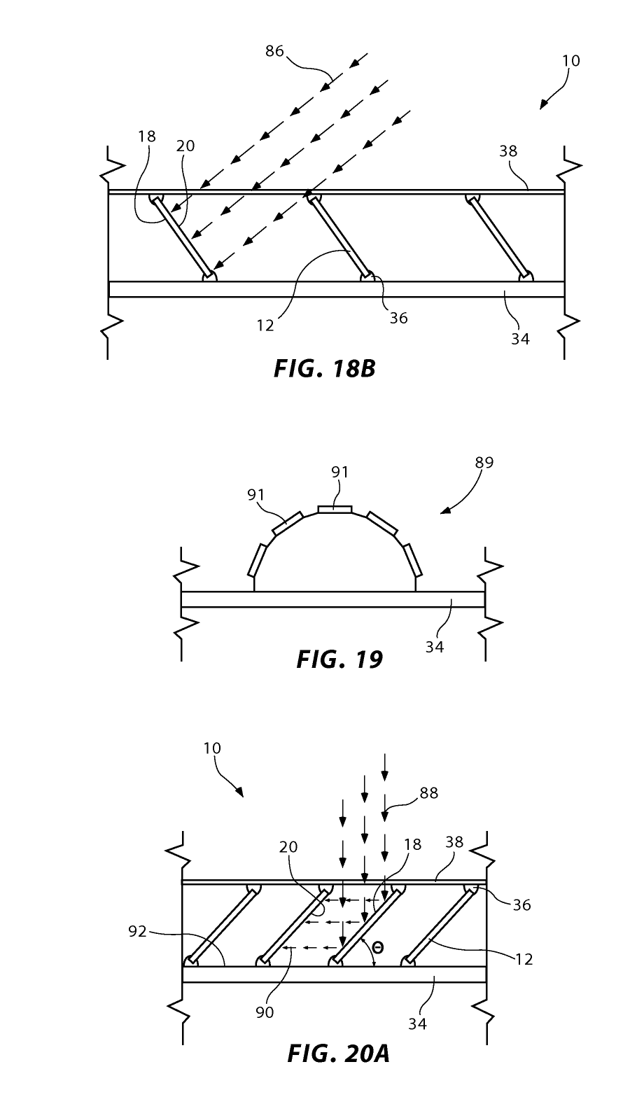

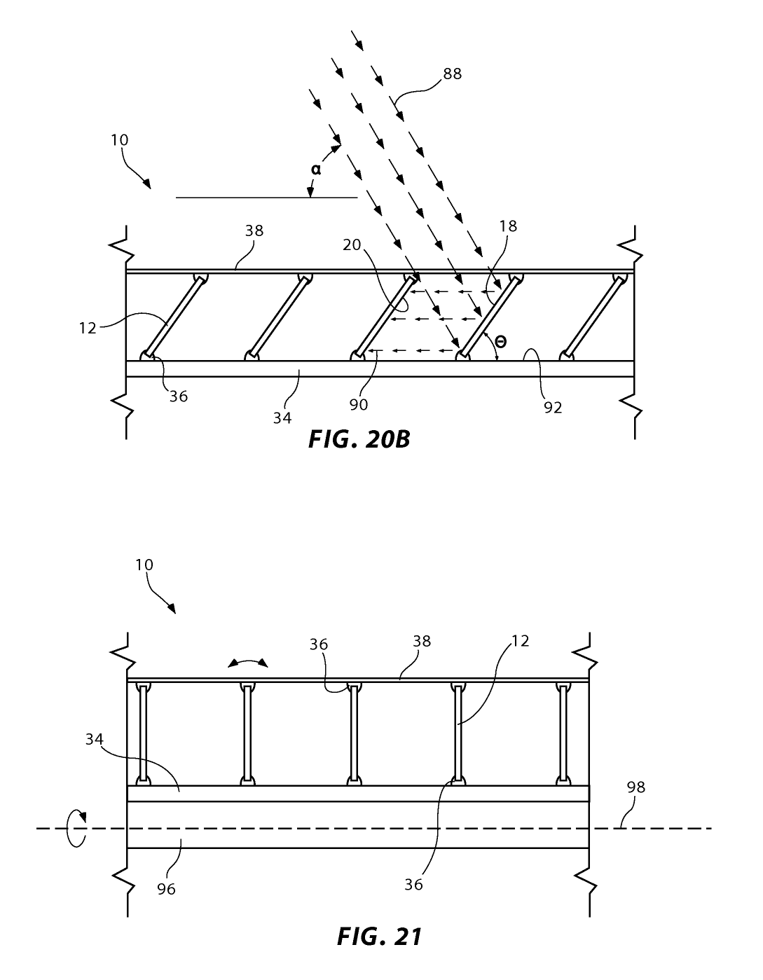

In another embodiment, a sensor assembly 89 comprising a group of photocells 91 or other radiation sensors oriented at various angles along, for example, a 180° arc, such as is shown in FIG. 18, may be aligned with the rotational direction of elongate solar cells 12 of an array may be associated with controller 46 so that relative strengths of output signals from the various photocells 91 may be used to empirically determine an optimum angle for the elongate solar cells 12. Of course, a combination of preprogramming of the controller 46 with a sensor assembly 89 may also be employed to optimize power output.

In additional embodiments, the plurality of elongate solar cells 12 may be bifacial (i.e., each of the first and second major faces 18 and 20 of the elongate solar cells 12 may be configured as solar collecting surfaces) and the controller 46 may be programmed to communicate with the actuators 42 to move each member 38, 40 and orient a solar collecting surface of each of the plurality of elongate solar cells 12 to a position that facilitates the absorption of direct incident solar radiation 88 by each elongate solar cell 12 and the absorption of solar radiation 90 reflected from a solar collecting surface of an adjacent elongate solar cell 12. For example, as shown in FIGS. 18A-18B, a first major face 18 of each of the plurality of elongate solar cells 12 may be oriented throughout the day to receive direct incident solar radiation 88 and to direct solar radiation 90 reflected from the first major face 18 toward a second major face 20 of an adjacent elongate solar cell 12. The second major face 20 of the adjacent elongate solar cell 12 may then collect at least a portion of the reflected solar radiation 90. As the angle of incident solar radiation 88 changes throughout the day, the angle of the major faces 18 and 20 of the plurality of elongate solar cells 12 may be oriented such that the solar radiation 90 reflected from a first major face 18 of an elongate solar cell 12 of the plurality is reflected toward a second major face 20 of an adjacent elongate solar cell 12, or such that the solar radiation reflected from a second major face 20 of an elongate solar cell 12 of the plurality is reflected toward a first major face 18 of an adjacent elongate solar cell 12.

For example, at one time of day the primary incident solar radiation 88 on the solar panel assembly 10 may be at an angle that is generally perpendicular to the solar panel assembly 10 (i.e., generally perpendicular to a surface 92 of the substrate 34), as shown in FIG. 19A. The first major faces 18 of the plurality of elongate solar cells 12 may be oriented at an angle θ of about 45 degrees (i.e., relative to the surface 92 of the substrate 34). In view of this, the incident solar radiation 88 may be received on the first major faces 18 of the plurality of elongate solar cells 12. A portion of the incident solar radiation 88 may be collected by the first major faces 18 of the plurality of elongate solar cells 12 and another portion of the incident solar radiation 90 may be reflected from the first major faces 18 of the plurality of elongate solar cells 12. The angle of each first major face 18 relative to the incident solar radiation 88 may cause the reflected solar radiation 90 to travel in a direction that is substantially parallel to the surface 92 of the substrate 34 and, for at least some of the plurality of elongate solar cells 12, the reflected solar radiation 90 will be directed toward a second major face 20 of an adjacent elongate solar cell 12. Then at least a portion of the reflected solar radiation 90 may be collected by the second major face 20 of the adjacent elongate solar cell 12.

At another time of day, the primary incident solar radiation 88 on the solar panel assembly 10 at an angle α that is about 45 degrees relative to the solar panel assembly 10 (i.e., about 45 degrees relative to the surface 92 of the substrate 34), as shown in FIG. 19B. The first primary surfaces 18 of the plurality of elongate solar cells 12 may be oriented at an angle θ of about 67.5 degrees (i.e., relative to the surface 92 of the substrate 34). In view of this, the incident solar radiation 88 may be received on the first major faces 18 of the plurality of elongate solar cells 12. A portion of the incident solar radiation 88 may be collected by first major faces 18 of the plurality of elongate solar cells 12 and another portion of the incident solar radiation 90 may be reflected from the first major faces 18 of the plurality of elongate solar cells 12. The angle of each first major face 18 relative to the incident solar radiation 88 may cause the reflected solar radiation 90 to travel in a direction that is generally parallel to the surface 92 of the substrate 34 and, for at least some of the plurality of elongate solar cells 12, the reflected solar radiation 90 will be directed toward a second major face 20 of an adjacent elongate solar cell 12. Then at least a portion of the reflected solar radiation 90 may be collected by the second major face 20 of the adjacent elongate solar cell 12.

In view of the foregoing, the plurality of elongate solar cells 12 of the solar panel assembly 10 may be caused to individually track the relative position of the sun throughout the day without the frame and substrate 34 of the solar panel assembly 10 moving. This may enable solar panel assemblies 10 to be positioned closer together and require less space, relative to solar panel assemblies that move to track the sun. Additionally, the solar panel assemblies 10 may be installed at an angle and position that is selected by the site, such as architectural features of a building, and the elongate solar cells 12 of the panel may be positioned for efficient collection of solar radiation. For example, solar panel assemblies 10 may be positioned to lie relatively flat against a roof of a building, and the array or arrays of elongate solar cells 12 of the solar panel assembly may then be positioned at an angle relative to the angle of the roof, such that efficient collection of solar radiation may be achieved by the solar panel assembly 10 even when the solar panel assembly 10 is positioned at an orientation that is arbitrary relative to the direction of incident solar radiation.

In additional embodiments, such as is shown if FIG. 20, a solar panel assembly 10 as described herein may be mounted for movement in a simple motion, such as on a pivot 96 for the rotation thereof about a single axis 98. The solar panel assembly 10 may be mounted with the plurality of elongate solar cells 12 positioned to rotate relative to the body (i.e., the substrate 34) of the solar panel assembly 10 in a direction that is different than the simple motion (e.g., perpendicular), such as a direction of rotation about the pivot 96 (i.e., the axis 98 of the pivot 96 may be non-parallel to the axis of rotation of each of the plurality of elongate solar cells 12). Thus, in operation, a compound movement and positioning of the elongate solar cells 12 may be achieved by the combined simple rotational movement of the base (i.e., the substrate 34) of the solar panel assembly 10 and the rotation of each of the plurality of elongate solar cells 12 relative to the base of the solar panel assembly 10. Such an arrangement may be extremely advantageous for use in geographical locations where the sun angle, relative to the vertical, varies widely throughout the year. Thus, in latitudes far removed from the equator, use of an arrangement such as that of FIG. 20 may maximize power production from a solar panel assembly throughout the four seasons.

### CONCLUSION

In one embodiment, a solar panel assembly may comprise at least one support member, a plurality of elongate solar cells, at least one motive member, and at least one actuator. Each elongate solar cell of the plurality may be pivotally coupled to the at least one support member at a first location on each elongate solar cell, and each motive member may be pivotally coupled to each elongate solar cell of the plurality of elongate solar cells at a second location on each elongate solar cell, the second location offset a distance from the first location. Additionally, each actuator may be operably coupled to the at least one motive member.

In a further embodiment, a method of manufacturing a solar panel assembly may comprise positioning a plurality of elongate solar cells relative to one another and pivotally coupling each of the plurality of elongate solar cells to at least one support member. The method may further comprise pivotally coupling each of the plurality of elongate solar cells to at least one motive member, and operably coupling at least one actuator to the at least one motive member.

In an additional embodiment a method of operating a solar panel assembly may comprise rotating each of a plurality of elongate solar cells within the solar panel assembly relative to each other of the plurality of elongate solar cells within the solar panel assembly.

While the invention is susceptible to various modifications and alternative specific embodiments have been shown by way of example in the drawings and have been described in detail herein. However, the invention is not intended to be limited to the particular forms disclosed. Rather, the invention is to cover all modifications, equivalents, and alternatives falling within the scope of the invention as defined by the following appended claims and their legal equivalents.

What is claimed is:

1. A solar panel assembly, comprising:
a plurality of elongate solar cells, each elongate solar cell of the plurality pivotally coupled to a at least one support member at a first location on each elongate solar cell;
at least one motive member pivotally coupled to of each elongate solar cell of the plurality of elongate solar cells at a second location on each elongate solar cell, the second location offset a distance from the first location; and
at least one actuator operably coupled to the at least one motive member.

2. The solar panel assembly of claim 1, wherein the first location on each elongate solar cell is a first edge.

3. The solar panel assembly of claim 2, wherein the second location on each elongate solar cell is a second edge, opposing the first edge.

4. The solar panel assembly of claim 1, further comprising at least one biasing structure operably coupled to the at least one motive member to oppose a motive force applied by the at least one actuator.

5. The solar panel assembly of claim 4, wherein the at least one biasing structure comprises at least one of a coil spring, a torsion spring, a leaf spring, an elastic material, and a weighted device.

6. The solar panel assembly of claim 1, further comprising a controller electrically coupled to the at least one actuator for controlling operation thereof.

7. The solar panel assembly of claim 6, wherein the controller is further electrically coupled to the plurality of elongate solar cells to receive electrical power therefrom.

8. The solar panel assembly of claim 1, wherein the at least one motive member comprises a plurality of elongate motive members.

9. The solar panel assembly of claim 8, wherein the plurality of elongate motive members comprise at least one of a beam, a wire and a cable.

10. The solar panel assembly of claim 9, wherein the plurality of elongate motive members comprise at least one of transparent beam.

11. The solar panel assembly of claim 1, wherein the at least one motive member comprises a transparent sheet motive member.

12. The solar panel assembly of claim 11, wherein the transparent sheet motive member comprises at least one of a glass sheet and a polymer sheet.

13. The solar panel assembly of claim 11, wherein the transparent sheet motive member extends over and completely covers the plurality of elongate solar cells.

14. The solar panel assembly of claim 1, wherein the at least one actuator comprises at least one of an electro-mechanical actuator, a transducer, a piezoelectric actuator, a motor, a stepper motor, a screw jack, a ball screw, a roller screw, a rack and pinion, a winch, a comb drive, a thermal bimorph, and an electroactive polymer.

15. The solar panel assembly of claim 1, wherein the first edge of each elongate solar cell of the plurality of elongate solar cells is pivotally coupled to the substrate by a flexible adhesive.

16. The solar panel assembly of claim 15, wherein the opposing second edge of each elongate solar cell of the plurality of elongate solar cells is pivotally coupled to the at least one motive member by a flexible adhesive.

17. The solar panel assembly of claim 1, wherein elongate solar cells of the plurality of elongate solar cells are electrically connected together by electrically conductive traces on the at least one support member.

18. The solar panel assembly of claim 1, wherein elongate solar cells of the plurality of elongate solar cells are electrically connected together by electrically conductive traces on the at least one motive member.

19. The solar panel assembly of claim 1, wherein elongate solar cells of the plurality of elongate solar cells are electrically connected together by wiring of a wire mesh.

20. The solar panel assembly of claim 1, wherein each elongate solar cell of the plurality of elongate solar cells has the same polarity as each other elongate solar cell of the plurality of elongate solar cells.

21. The solar panel assembly of claim 1, wherein each elongate solar cell of the plurality of elongate solar cells has the opposite polarity of each adjacent elongate solar cell of the plurality of elongate solar cells.

22. The solar panel assembly of claim 1, wherein a spacing between the first edge of each elongate solar cell and the first edge of each adjacent elongate solar cell of the plurality of elongate solar cells is less than the height of each elongate solar cell.

23. A method of manufacturing a solar panel assembly, the method comprising:
positioning a plurality of elongate solar cells relative to one another;
pivotally coupling each of the plurality of elongate solar cells to at least one support member;
pivotally coupling each of the plurality of elongate solar cells to at least one motive member; and
operably coupling at least one actuator to the at least one motive member.

24. The method of claim 23, further comprising operably coupling at least one biasing structure to the at least one motive member to oppose a motive force applied by the at least one actuator.

25. The method of claim 24, wherein operably coupling the at least one biasing structure to the second end of the at least one member further comprises coupling at least one of a coil spring, a torsion spring, a leaf spring, an elastic material, and a weighted device to the second end of the at least one member.

26. The method of claim 23, further comprising electrically coupling a controller to the at least one actuator to control operation thereof.

27. The method of claim 26, further comprising electrically coupling the controller to the plurality of elongate solar cells to receive electrical power therefrom.

28. The method of claim 23, wherein pivotally coupling the second edge of each of the plurality of elongate solar cells to the at least one motive member further comprises pivotally coupling the second edge of each of the plurality of elongate solar cells to at least one of an elongate member, a beam, a wire, a cable, a transparent beam, a transparent sheet member, a glass sheet, and a polymer sheet.

29. The method of claim 23, wherein operably coupling the at least one actuator to the at least one motive member comprises coupling at least one of an electro-mechanical actuator, a transducer, a piezoelectric actuator, a motor, a stepper motor, a screw jack, a ball screw, a roller screw, a rack and pinion, a winch, a comb drive, a thermal bimorph, and an electroactive polymer to the first end of the at least one motive member.

30. The method of claim 23, further comprising:
applying an adhesive to at least one of the first edge of each elongate solar cell of the plurality of elongate solar cells and the at least one support member; and
curing the adhesive to form a flexible structure to pivotally couple the first edge of each of the plurality of elongate solar cells to the at least one support member.

31. The method of claim 30, further comprising:
applying an adhesive to at least one of the second edge of each elongate solar cell of the plurality of elongate solar cells and the at least one motive member; and
curing the adhesive to form a flexible structure to pivotally couple the second edge of each of the plurality of elongate solar cells to the at least one motive member.

32. A method of operating a solar panel assembly, the method comprising rotating each of a plurality of elongate solar cells relative to each other of the plurality of elongate solar cells within the solar panel assembly.

33. The method of claim 32, further comprising utilizing at least one actuator to simultaneously orient a solar collecting surface of each of the plurality of elongate solar cells.

34. The method of claim 33, further comprising communicating with the at least one actuator with a programmed controller to cause the at least one actuator to alter an angle of orientation of the plurality of elongate solar cells.

35. The method of claim 32, further comprising orienting a solar collecting surface of each of the plurality of elongate solar cells throughout the day to be relatively perpendicular to a primary direction of incident solar radiation.

36. The method of claim 32, further comprising orienting a first major face of the plurality of elongate solar cells throughout the day to receive direct incident solar radiation and for at least some of the plurality of elongate solar cells to direct solar radiation reflected from the first major face toward a second major face of an adjacent elongate solar cell.

37. The method of claim 36, wherein directing solar radiation reflected from the first major face toward a second major face of an adjacent elongate solar cell further comprises directing solar radiation reflected from the first major face in a direction substantially parallel to a substrate attached to each of the plurality of elongate solar cells.

38. The method of claim 32, further comprising rotating the solar panel assembly about an axis that is non-parallel with an axis of rotation of any of the plurality of elongate solar cells to effect compound rotational movement of each of the plurality of elongate solar cells.
